(19) United States
(12) Patent Application Publication
(10) Pub. No.: US 2026/0129925 A1
(43) Pub. Date: May 7, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: CHIA-HAO CHANG, HSINCHU CITY (TW); KUO-CHENG CHIANG, HSINCHU COUNTY (TW); CHIH-HAO WANG, HSINCHU COUNTY (TW); I-HAN HUANG, NEW TAIPEI CITY (TW)

(21) Appl. No.: 18/939,582

(22) Filed: Nov. 7, 2024

(51) Int. Cl. H01L 29/06; H01L 21/762; H01L 21/768; H01L 27/088; H01L 29/423; H01L 29/66; H01L 29/775

(52) U.S. Cl. CPC H10D 62/115; H10D 30/014; H10D 30/43; H10D 64/017; H10D 84/834; H10W 10/014; H10W 10/17; H10W 20/081; H10D 30/6735; H10D 62/121

(57) ABSTRACT

A semiconductor structure includes a metal gate structure and an isolation structure adjacent to the metal gate structure. The isolation structure includes a first dielectric layer, a second dielectric layer over the first dielectric layer, and a third dielectric layer over the second dielectric layer. The first dielectric layer includes carbon of a first concentration, the second dielectric layer includes carbon of a second concentration, and the third dielectric layer includes carbon of a third concentration. The third concentration is greater than the second concentration, and the second concentration is greater than the first concentration.

### BACKGROUND

The electronics industry has experienced an ever-increasing demand for smaller and faster electronic devices that are able to support greater numbers of increasingly complex and sophisticated functions. Accordingly, there is a continuing trend in the semiconductor industry to manufacture low-cost, high-performance, low-power integrated circuits (ICs). Thus far these goals have been achieved in large part by scaling down semiconductor IC dimensions (e.g., minimum feature size) and thereby improving production efficiency and reducing associated costs. However, such downscaling has also introduced increased complexity to the semiconductor manufacturing process.

As technology nodes achieve progressively smaller scales, in some IC designs, researchers have hoped to replace a typical polysilicon gate with a metal gate to improve device performance by decreasing the feature sizes. One approach to forming the metal gate is called a “gate-last” approach, sometimes referred to as a replacement polysilicon gate (RPG) approach. In the RPG approach, the metal gate is fabricated last, which allows for a reduced number of subsequent operations.

Further, as dimensions of a transistor decrease, a thickness of a gate dielectric layer may be reduced to maintain performance with a decreased gate length. In order to reduce gate leakage, a high dielectric constant (high-k or HK) gate dielectric layer is used to provide a performance comparable to that provided by a typical gate oxide used in larger technology nodes. A high-k metal gate (HKMG) approach including a metal gate electrode and the high-k gate dielectric layer is therefore recognized. However, the HKMG approach is a complicated approach, and many issues arise.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view illustrating portions of a semiconductor structure in accordance with aspects of the present disclosure in one or more embodiments.

FIG. 1B is a cross-sectional view of the semiconductor structure in accordance with aspects of the present disclosure in one or more embodiments.

FIG. 1C is a cross-sectional view of the semiconductor structure e in accordance with aspects of the present disclosure in other embodiments.

FIG. 2 is a top view of a semiconductor structure in accordance with aspects of the present disclosure in one or more embodiments.

FIGS. 3A and 3B are cross-sectional views of a portion of the semiconductor structure taken along a line A-A′ of FIG. 2 in accordance with aspects of the present disclosure in various embodiments.

FIG. 4 is an enlarged view of FIG. 3A and FIG. 3B in accordance with aspects of the present disclosure in one or more embodiments.

FIG. 5 is a flowchart representing a method for forming a semiconductor structure according to aspects of the present disclosure.

FIG. 6 to FIGS. 16A and 16B are schematic drawings at various stages in the method for forming a semiconductor structure according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

A manufacturing process flow for IC devices can be categorized into front-end-of-line (FEOL), middle-end-of-line (MEOL), and back-end-of-line (BEOL) process categories. The FEOL category involves processes related to the fabrication of IC devices, such as transistors, including forming isolation structures, gate structures, and source/drain structures. The MEOL categories encompasses processes related to the fabrication of connecting structures that connect to the conductive features of the IC devices. The BEOL categories involves processes related to the fabrication of multilayer interconnect (MLI) structures that electrically connect the IC devices and the connecting structures fabricated by FEOL and MEOL processes.

In some embodiments, MD refers to “metal-to-device” or “metal-to-drain” contact, which involves connecting the source/drain structures of transistors to a BEOL interconnection, enabling electrical connection between the FEOL structures and the BEOL interconnection. In some embodiments, a source/drain contact may be referred to as MD. As feature sizes continue to decrease, fabrication processes become more challenging. For example, the source/drain contacts over adjacent source/drain structures of adjacent transistors may be formed closer than expected. In such comparative approaches, unwanted dielectric loss may occur.

According to one embodiment of the present disclosure, a semiconductor structure including a multi-layered isolation structure and a method thereof are provided. The semiconductor structure includes the multi-layered isolation structure formed in a cut metal gate (CMG) operations during MEOL processes. Further, the multi-layered isolation structure formed between conductive structures, such as the abovementioned MDs, serves as a barrier between two adjacent MDs. Accordingly, a process window in enlarged and yield is improved.

In some embodiments, a CMG process is used to interrupt a continuous metal gate structure. The term “cut metal gate process” refers to a fabrication process in which after a metal gate feature (e.g., a high-k metal gate or HKMG) replaces a sacrificial gate structure (e.g., a polysilicon gate), the metal gate feature is cut (e.g., by an etching process) to separate the metal gate feature into two or more portions. Each portion functions as a metal gate structure for an individual transistor.

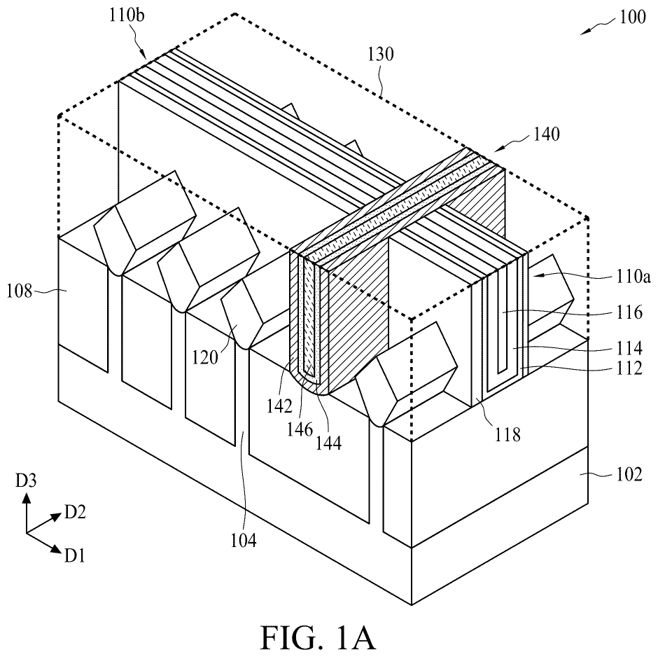

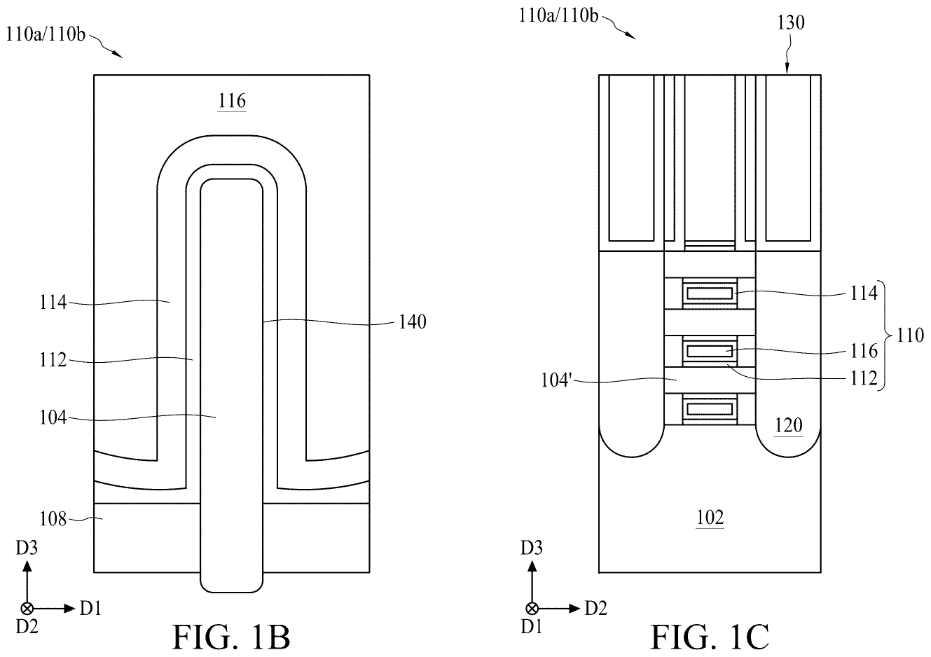

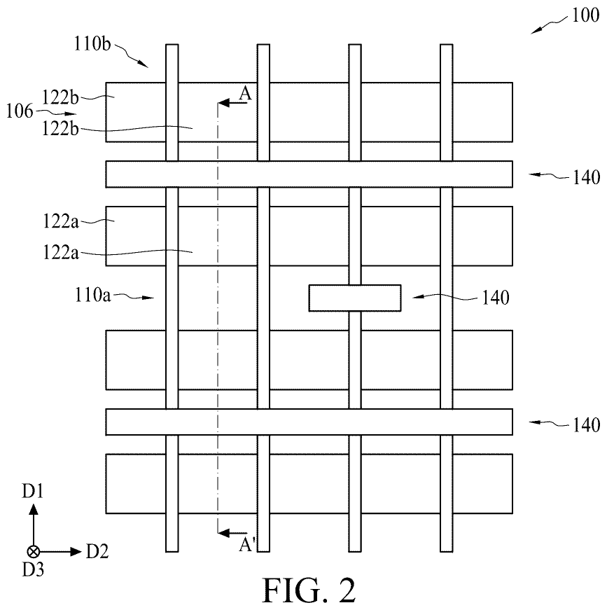

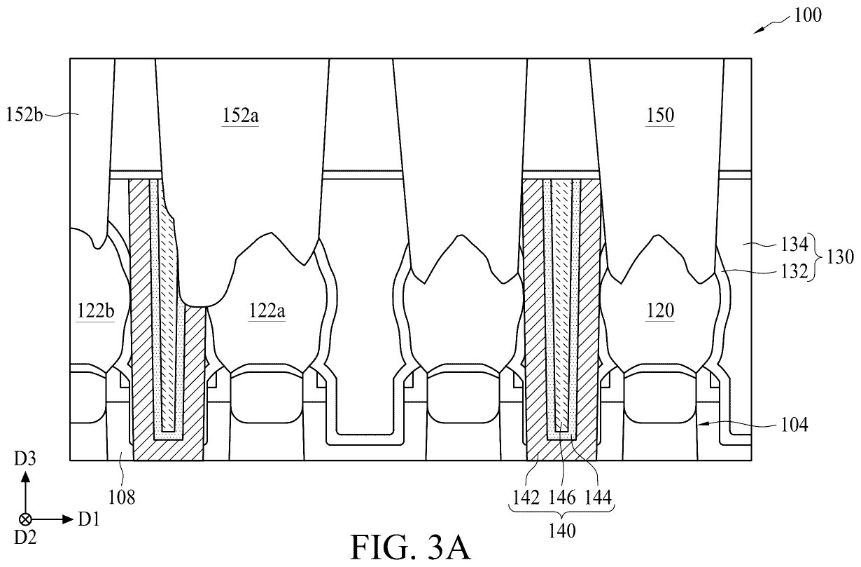

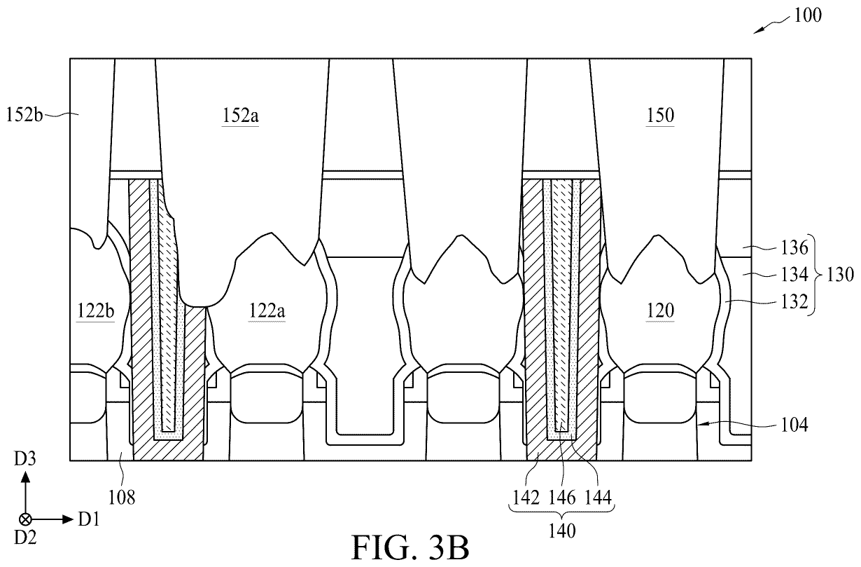

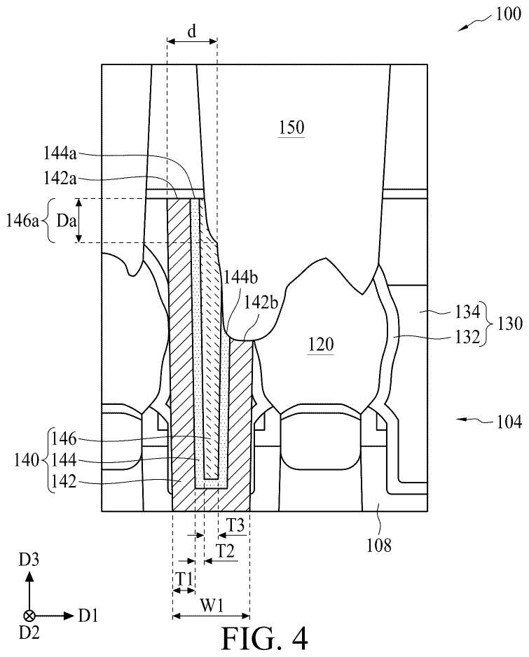

Please refer to FIGS. 1A to 4, wherein FIG. 1A is a perspective view of a semiconductor structure according to aspects of the present disclosure, FIG. 1B is a cross-sectional view of a semiconductor structure in accordance with some embodiments of the present disclosure, FIG. 1C is a cross-sectional view of a semiconductor structure in accordance with other embodiments of the present disclosure, FIG. 2 is a top view illustrating a portion of a layout structure of a semiconductor structure in accordance with aspects of the present disclosure in one or more embodiments, FIGS. 3A and 3B are cross-sectional views of a portion of the semiconductor structure taken along a line A-A′ of FIG. 2 in various embodiments, and FIG. 4 is an enlarged view of FIGS. 3A and 3B in one or more embodiments.

Referring to FIGS. 1A to 4, the semiconductor structure 100 includes a substrate 102, a plurality of fins 104 protruding from the substrate 102 and disposed in an active region 106, an isolation structure 108 over the substrate 102, and a first metal gate structure 110a and a second metal gate structure 110b disposed over the fins 104 and the isolation structure 108. In some embodiments, the semiconductor structure 100 may include a substrate 102, a plurality of nanosheets 104′ over the substrate 102 and disposed in an active region 106, an isolation structure 108, and a first metal gate structure 110a and a second metal gate structure 110b wrapped around the nanosheets 104′.

The semiconductor structure 100 further includes epitaxial source/drain structures 120 disposed at two sides of the first and second metal gate structures 110a and 110b, respectively. The semiconductor structure 100 further includes a dielectric structure 130 surrounding the first and second metal gate structures 110a and 110b, the fins 104, and the epitaxial source/drain structures 120. Further, the semiconductor structure 100 includes a multi-layered isolation structure 140 disposed over the substrate 102 and adjacent to the first and second metal gate structures 110a and 110b. In some embodiments, the multi-layered isolation structure 140 is disposed between the adjacent first and second metal gate structures 110a and 110b, and separates the first and second metal gate structures 110a and 110b from each other.

In some embodiments, the substrate 102 may be a semiconductor substrate such as a silicon substrate. The substrate 102 may also include other semiconductors material such as germanium (Ge), silicon carbide (SiC), silicon germanium (SiGe), or diamond. Alternatively, the substrate 102 may include a compound semiconductor and/or an alloy semiconductor. The substrate 102 may include various layers, including conductive or insulating layers formed on a semiconductor substrate. The substrate 102 may include various doping configurations depending on design requirements, as is known in the art. For example, different doping profiles (e.g., n wells or p wells) may be formed on the substrate 102 in regions designed for different device types (e.g., n-type field-effect transistors (NFET), or p-type field-effect transistors (PFET)). A suitable doping operation may include ion implantation of dopants and/or diffusion processes.

The fin 104 includes one or more semiconductor materials such as Si, Ge, SiC, GaAs, GaP, InP, InAs, InSb, SiGe, GaAsP, AlInP, AlGaAs, GaInAs, GaInP, or GaInAsP. In some embodiments, the fin 104 may include alternately stacked layers of two different semiconductor materials, such as layers of Si and SiGe alternately stacked. The fin 104 may additionally include dopants for improving a performance of a FinFET device. For example, the fin 104 may include n-type dopant(s) such as phosphorus (P) or arsenic (As), or p-type dopant(s) such as boron (B) or indium (In).

The isolation structure 108 may include silicon oxide (SiO), silicon nitride (SiN), silicon oxynitride (SiON), fluoride-doped silicate glass (FSG), a low-k dielectric material, and/or other suitable insulating materials. The isolation structure 108 may include shallow trench isolation (STI) features. Other isolation structures, such as field oxide, local oxidation of silicon (LOCOS), and/or other suitable structures are possible. The isolation structure 108 may include a multi-layer structure, for example, a structure with one or more thermal oxide liner layers adjacent to the fins 104.

The first metal gate structure 110a and the second metal gate structure 110b respectively include a high-k gate dielectric layer 112, a work function metal layer 114 over the high-k gate dielectric layer 112, and a gap-filling metal layer 116. In some embodiments, the first and second metal gate structures 110a and 110b are also referred to as a high-k metal gate (or HKMG). In some embodiments, the first and second metal gate structures 110a and 110b may further include an interfacial layer (IL) (not shown) under the high-k gate dielectric layer 112.

The high-k gate dielectric layer 112 may include one or more high-k dielectric materials (or one or more layers of high-k dielectric materials), such as hafnium silicon oxide (HfSiO), hafnium oxide (HfO₂), alumina (Al₂O₃), zirconium oxide (ZrO₂), lanthanum oxide (La₂O₃), titanium oxide (TiO₂), yttrium oxide (Y₂O₃), strontium titanate (SrTiO₃), or a combination thereof. The work function metal layer 114 may include one or more metal layers. The work function metal layer 114 may be a p-type or an n-type work function layer depending on the type (PFET or NFET) of the device. The p-type work function layer comprises a metal with a sufficiently large effective work function, selected from but not restricted to the group of titanium nitride (TiN), tantalum nitride (TaN), ruthenium (Ru), molybdenum (Mo), tungsten (W), platinum (Pt), and combinations thereof. The n-type work function layer comprises a metal with sufficiently low effective work function, selected from but not restricted to the group of titanium (Ti), aluminum (Al), tantalum carbide (TaC), tantalum carbide nitride (TaCN), tantalum silicon nitride (TaSiN), titanium silicon nitride (TiSiN), and combinations thereof. The gap-filling metal layer 116 may include Al, W, cobalt (Co), and/or other suitable materials.

As shown in FIGS. 1 to 3B, the first and second metal gate structures 110a and 100b extend in a first direction D1, and the fins 104 extend in a second direction D2. The second direction D2 is different from the first direction D1. Generally, the second direction D2 is perpendicular to the first direction D1. Further, the fins 104 protrude from the substrate 102 in a third direction D3. In some embodiments, the third direction D3 is perpendicular to both the first direction D1 and the second direction D2. In some embodiments, the first and/or second metal gate structures 110a and 110b respectively cover and engage at least one of the respective fins 104 to form an individual FinFET device, as shown in FIG. 1B. In some embodiments, the first and/or second metal gate structures 110a and 110b respectively wraps around each of the nanosheets 104′ to form a GAA FET device, as shown in FIG. 1C. In some embodiments, the first and second metal gate structures 110a and 110b separated by the multi-layered isolation structure 140 have a same conductivity type. In some embodiments, the first and second metal gate structures 110a and 110b separated by the multi-layered isolation structure 140 may have same materials. In some embodiments, the multi-layered isolation structure 140 may be said to be disposed between two FinFET devices, and the two FinFET devices have a same conductive type.

In some embodiments, the semiconductor structure 100 further includes gate spacers 118 formed over sidewalls of the first and second metal gate structures 110a and 110b, respectively. The gate spacers 118 may include a single-layer structure or a multi-layer structure, and include dielectric materials such as silicon nitride, silicon carbide, or silicon carbonitride.

In some embodiments, the epitaxial source/drain structures 120 may be formed, by way of example and not limitation, depending on the type of transistor (e.g., n-type or p-type) to include: (i) boron (B) doped SiGe, B-doped Ge, or B-doped germanium tin (GeSn) for p-type transistors; and (ii) carbon-doped. Si (Si:C), phosphorus-doped Si (Si:P) or arsenic doped Si (Si:As) for n-type transistors. Further, the epitaxial source/drain structures 120 may include multiple layers (e.g., two layers, three layers, or more) with different dopant concentrations and/or crystalline microstructures, crystallographic orientations, etc. The source/drain structures may refer to a source or a drain, individually or collectively dependent upon the context.

As shown in FIGS. 2, 3A and 3B, the epitaxial source/drain structures 120 may include a first source/drain 122a disposed at two sides of the first metal gate structure 110 a, and a second source/drain 122b disposed at two sides of the second metal gate structure 110 b. The first source/drain 122a and the second source/drain 122b both extend in the second direction D2, but are separated from each other. In some embodiments, the first source/drain 122a and the second source/drain 122b are separated from each other by the multi-layered isolation structure 140, as shown in FIGS. 3A and 3B.

The dielectric structure 130 may include a contact etch stop layer (CESL) 132 and an interlayer dielectric (ILD) layer 134, as shown in FIGS. 3A and 3B. In some embodiments, the CESL 132 can include silicon nitride, silicon oxynitride, and/or other applicable materials. The ILD layer 134 may include multilayers made of multiple dielectric materials, such as silicon oxide, silicon nitride, silicon oxynitride, silicon oxide formed from tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon-doped silicon oxide, amorphous fluorinated carbon, parylene, bis-benzocyclobutenes (BCB), and polyimide.

Referring to FIG. 3B, in some embodiments, the dielectric structure 130 may further include a cap layer 136 disposed over the ILD layer 134. The cap layer 136 may include a material different from that of the ILD layer 134. In some embodiments, the cap layer 136 may include, for example but not limited thereto, silicon oxide, silicon nitride, aluminum oxide, silicon oxynitride, silicon oxycarbide, silicon carbon oxynitride, or a combination thereof.

In some embodiments, the semiconductor structure 100 further includes a plurality of connecting structures 150. As shown in FIGS. 3A and 3B, the connecting structures 150, which may be referred to as source/drain contacts, are formed over and electrically connected to the epitaxial source/drain structures 120. For example, the connecting structures 150 may include a first source/drain contact 152a and a second source/drain contact 152b. The connecting structures 150 may include tungsten, although other suitable materials such as aluminum, copper, tungsten nitride, ruthenium, silver, gold, rhodium, molybdenum, nickel, cobalt, cadmium, zinc, alloys of these, combinations thereof, and the like, may alternatively be utilized. In some embodiments, metal silicide structures (not shown) may be formed between each connecting structure 150 and a respective epitaxial source/drain structure 120. In some embodiments, a diffusion barrier layer (not shown) may be formed between the connecting structure 150 and the dielectric structure 130. In some embodiments, adjacent connecting structures 150 are separated from each other in the first direction D1. In some embodiments, the adjacent connecting structures 150 are separated from each other by, at least, the multi-layered isolation structure 140, as shown in FIGS. 3A and 3B.

Referring to FIGS. 1 to 4, the multi-layered isolation structure 140 extends in the second direction D2, thereby cutting the metal gate structure 110 into sections. In some embodiments, a width W1 of the multi-layered isolation structure 140 may be between approximately 3 nanometers and approximately 40 nanometers, but the disclosure is not limited thereto. In some embodiments, the multi-layered isolation structure 140 includes a first dielectric layer 142, a second dielectric layer 144 and a third dielectric layer 146. The first and third dielectric layers 142 and 146 may include silicon oxide, silicon nitride, aluminum oxide, silicon oxynitride, silicon oxycarbide, silicon carbon oxynitride, or a combination thereof. However, a material of the first dielectric layer 142, a material of the second dielectric layer 144 and a material of the third dielectric layer 146 are different from each other. For example but not limited thereto, in some embodiments, the first dielectric layer 142 may include a silicon nitride layer, and the second dielectric layer 144 may include a silicon oxide layer. The third dielectric layer 146 may include the abovementioned dielectric materials with other dopants. For example but not limited thereto, the dopants may include silicon, aluminum, hafnium, oxygen, nitrogen, titanium, or combinations thereof. In some embodiments, a dopant concentration in the third dielectric layer 146 may be between approximately 0.1% and approximately 50%, but the disclosure is not limited thereto. Due to the dopants in the dielectric materials, a hardness of the third dielectric layer 146 is greater than a hardness of the first dielectric layer 142, and greater than a hardness of the second dielectric layer 144. In such embodiments, the third dielectric layer 146 is referred to as a hard core in the multi-layered isolation structure 140. In some embodiments, a thickness T3 of the third dielectric layer 146 is greater than a thickness T1 of the first dielectric layer 142, and greater than a thickness T2 of the second dielectric layer 144. In some embodiments, the thickness T1 of the first dielectric layer 142 is greater than the thickness T2 of the second dielectric layer 144, but the disclosure is not limited thereto. In some embodiments, the thickness T1 of the first dielectric layer 142 is between approximately 0.1 nanometer and approximately 10 nanometers, but the disclosure is not limited thereto. In some embodiments, the thickness T2 of the second dielectric layer 144 is between approximately 0.1 nanometer and approximately 10 nanometers, but the disclosure is not limited thereto. In some embodiments, the thickness T3 of the third dielectric layer 146 is between approximately 1 nanometer and approximately 20 nanometers.

Referring to FIG. 4, in some embodiments, the first dielectric layer 142 and the second dielectric layer 144 respectively include a U shape, and the third dielectric layer 146 includes an I shape. In such embodiments, sidewalls and a bottom of the third dielectric layer 146 are in contact with the second dielectric layer 144. Further, a topmost surface of the U-shaped first dielectric layer 142, a topmost surface of the U-shaped second dielectric layer 144 and a top surface of the third dielectric layer 146 are aligned with each other.

However, in some embodiments, the first dielectric layer 142 may have a J shape, as shown in FIG. 4. In such embodiments, the first dielectric layer 142 has a first top surface 142a and a second top surface 142b, wherein the first top surface 142a is higher than the second top surface 142b. In some embodiments, the connecting structure 150 (i.e., the first source/drain contact 152a or the second source/drain contact 152b) is in contact with the multi-layered isolation structure 140. In some embodiments, the connecting structure 150 is in contact with the third dielectric layer 146. In such embodiments, a portion of the first dielectric layer 142 that is proximal to the connecting structure 150 may be in contact with the connecting structure 150 while another portion of the first dielectric layer 142 that is distal to the connecting structure 150 may be separated from the connecting structure 150 by, at least, the third dielectric layer 146. For example, the second top surface 142b is in contact with the connecting structure 150, and the first top surface 142a is separated from connecting structure 150 by the third dielectric layer 146. Further, a lateral distance d between a bottommost surface of the connecting structure 150 to a sidewall of the first dielectric layer 142 that is most distal to the connecting structure 150 may be between approximately 2 nanometers and approximately 15 nanometers, but the disclosure is not limited thereto.

In some embodiments, the second dielectric layer 144 may have a J shape, as shown in FIG. 4. In such embodiments, the second dielectric layer 144 has a first top surface 144a and a second top surface 144b, wherein the first top surface 144a is higher than the second top surface 144b. In such embodiments, a portion of the second dielectric layer 144 that is proximal to the connecting structure 150 may be in contact with the connecting structure 150 while another portion of the second dielectric layer 144 that is distal to the connecting structure 150 may be separated from the connecting structure 150 by, at least, the third dielectric layer 146. For example, the second top surface 144b is in contact with the connecting structure 150, and the first top surface 144a is separated from the connecting structure 150 by the third dielectric layer 146.

In some embodiments, a portion of the third dielectric layer 146 may be in contact with the connecting structure 150 (i.e., the first source/drain contact 152a or the second source/drain contact 152b). In such embodiments, a portion of the dielectric layer 146 may have a reduced thickness less than the thickness T3. Further, such portion is referred to as an attenuated portion 146a. In some embodiments, a depth Da of the attenuated portion 146a may be between approximately 0.1 nanometer and approximately 20 nanometers, but the disclosure is not limited thereto.

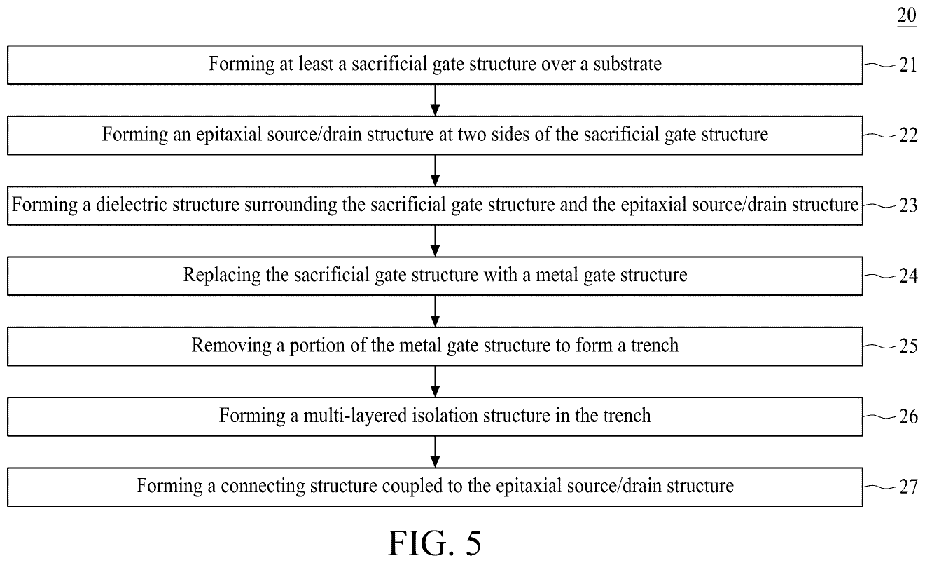

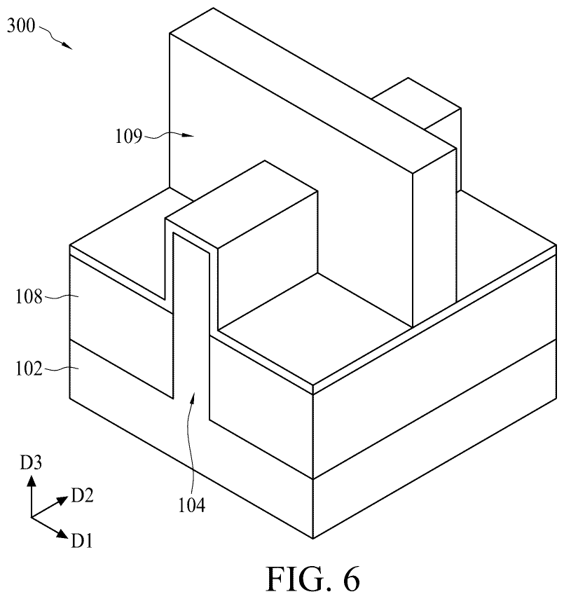

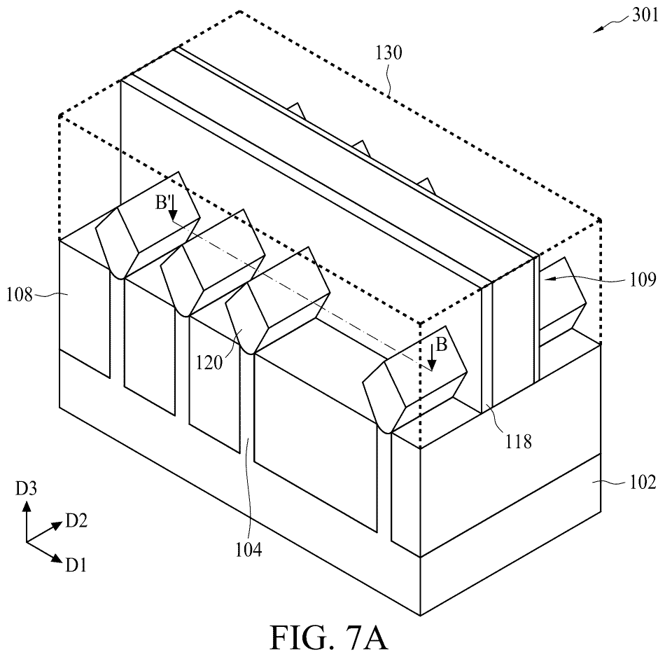

FIG. 5 is a flowchart representing a method 20 for forming a semiconductor structure according to aspects of one or more embodiments of the present disclosure. While the disclosed method 20 is illustrated and described herein as a series of acts or operations, it should be appreciated that an order of the illustrated acts or operations is not to be interpreted in a limiting sense. For example, some operations may be performed in a different order and/or concurrently with other acts or operations apart from those illustrated and/or described herein. In addition, not all illustrated operations may be required to implement one or more aspects or embodiments of the invention described herein. Further, one or more of the operations described herein may be carried out in one or more separate operations and/or phases.

In operation 21, a sacrificial gate structure is formed over a substrate. FIG. 6 is a perspective view of an intermediate semiconductor structure 300 according to some embodiments corresponding to operation 21. In some embodiments, operation 21 may include further steps. For example, as shown in FIG. 6, a substrate 102 is received, and a plurality of fins 104 are formed over the substrate 102. In some embodiments, the fins 104 are formed in an active region 106 defined by an isolation structure 108. Further, in some embodiments, the isolation structure 108 surrounds a portion of the fins 104.

The sacrificial gate structure 109 is formed over the substrate 102 and the fins 104. In some embodiments, the sacrificial gate structure 109 extends in a first direction D1, while the fins 104 extend in a second direction D2. Further, a portion of the fin 104 is covered by the sacrificial gate structure 109 and serves as a channel region. In some embodiments, the sacrificial gate structure 109 may include a dielectric layer and a sacrificial semiconductor layer. In some embodiments, the sacrificial semiconductor layer is made of polysilicon, but the disclosure is not limited thereto.

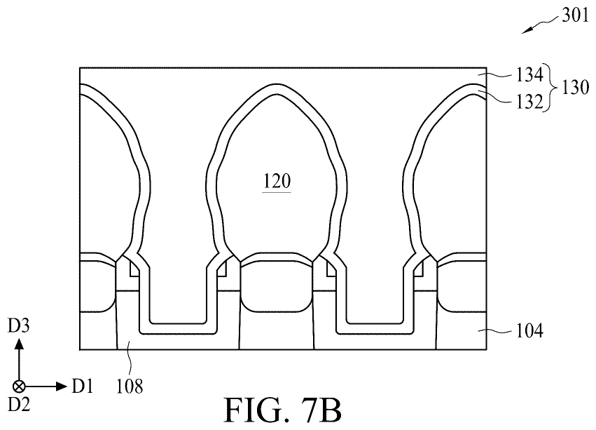

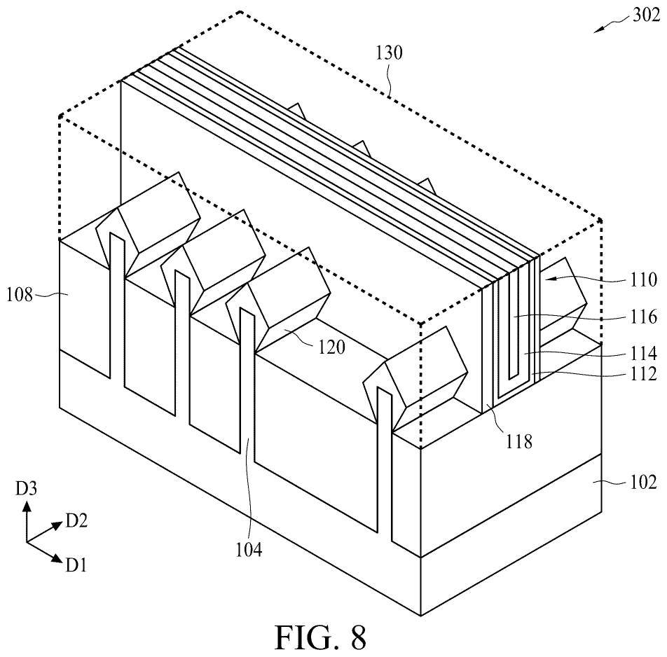

In some embodiments, a gate spacer 118 (shown in FIG. 7A) can be formed over sidewalls of the sacrificial gate structure 109. In some embodiments, the gate spacer 118 is made of silicon nitride (SiN), silicon carbide (SiC), silicon oxide (SiO), silicon oxynitride (SiON), silicon carbide or any other suitable material, but the disclosure is not limited thereto. In some embodiments, the gate spacer 118 is formed by deposition and etch-back operations.

FIG. 7A is a perspective view of an intermediate semiconductor structure 301 according to some embodiments corresponding to operation 22, and FIG. 7B is a cross-sectional view taken along line B-B′ of FIG. 7A. In some embodiments, in operation 22, epitaxial source/drain structures 120 are formed over the fins 104 at two opposite sides of the sacrificial gate structure 109. In some embodiments, heights of the epitaxial source/drain structures 120 may be greater than a height of the fin 104. In some embodiments, the epitaxial source/drain structures 120 may be formed by forming recesses in the fin 104 and growing a strained material in the recesses by an epitaxial (epi) process. In addition, a lattice constant of the strained material may be different from a lattice constant of the fin 104. Accordingly, the epitaxial source/drain structures 120 may serve as stressors that improve carrier mobility.

Still referring to FIGS. 7A and 7B, in some embodiments, in operation 23, a dielectric structure 130 is formed to surround the sacrificial gate structure 109 and the epitaxial source/drain structures 120. The dielectric structure 130 may include a CESL 132 and an ILD layer 134. In some embodiments, a top surface of the sacrificial gate structure 109 may be exposed through the dielectric structure 130, as shown in FIG. 7A.

In operation 24, the sacrificial gate structure 109 is replaced with a metal gate structure. Please refer to FIG. 8, which is a perspective view of an intermediate semiconductor structure 302 according to some embodiments corresponding to operation 24. In some embodiments, operation 24 includes further processes. For example, the sacrificial gate structure 109 is removed to form a gate trench (not shown). As shown in FIG. 8, a high-k dielectric layer 112 is formed in the gate trench. In some embodiments, an IL layer may be formed prior to the forming of the high-k dielectric layer 112, though not shown. The IL layer may include an oxide-containing material such as SiO or SiON. In some embodiments, the IL layer covers portions of the fin 104 exposed in the gate trench. The high-k dielectric layer 112 is conformally formed in the gate trench.

Still referring to FIG. 8, a work function metal layer 114 is subsequently formed in the gate trench. The work function metal layer 114 may be formed by CVD, PVD and/or another suitable process. Subsequently, the gate trench is filled with a gap-filling metal layer 116. The gap-filling metal layer 116 may include metal materials having low resistance, and may be formed by CVD, PVC, plating and/or other suitable processes. Materials for forming the high-k gate dielectric layer 112, the work function metal layer 114 and the gap-filling metal layer 116 are similar to those described above; therefore, repeated descriptions are omitted in the interest of brevity. Further, a CMP is performed to remove superfluous layers, thereby forming a metal gate structure 110 surrounded by the dielectric structure 130. As shown in FIG. 8, a top surface of the dielectric structure 130 and a top surface of the metal gate structure 110 are aligned or level with each other.

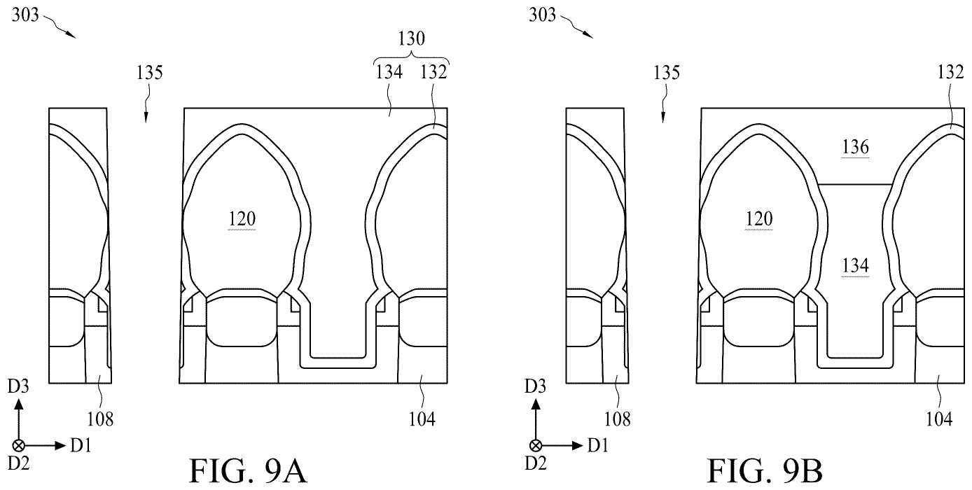

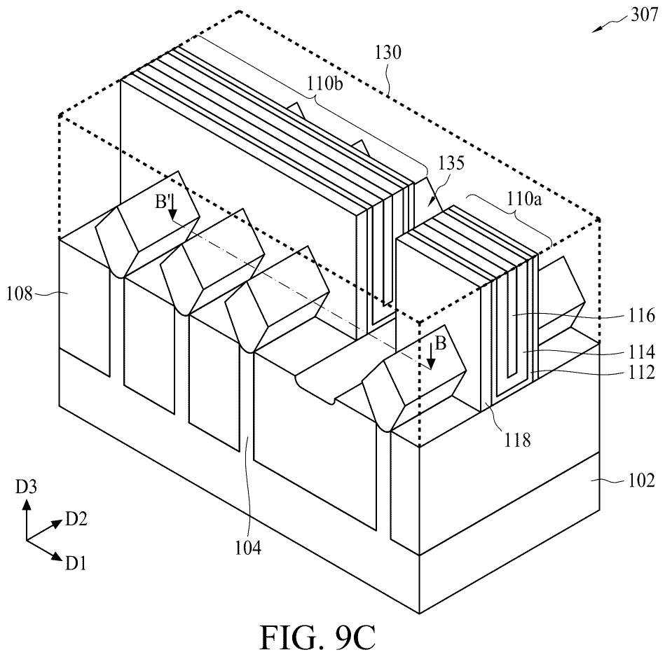

In operation 25, a portion of the metal gate structure 110 is removed to form a trench 135. Please refer to FIGS. 9A to 9C, wherein FIG. 9C is a perspective view of an intermediate semiconductor structure 303 according to some embodiments corresponding to operation 25, and FIGS. 9A and 9B are cross-sectional views taken along line B-B′ of FIG. 9C in accordance with various embodiments. As shown in FIG. 9C, in some embodiments, the trench 135 extends in the second direction D2. In some embodiments, the trench 135 can be formed between the fins 104, thus exposing the dielectric structure 130 through the trench 135. In some embodiments, the dielectric structure 130 may be referred to as sidewalls of the trench 135, while the isolation structure 108 is exposed through the trench 135 and may be referred to as a bottom of the trench 135. In some embodiments, the trench 135 cuts the metal gate structure 110 into a first metal gate structure 110a and a second metal gate structure 110b. In such embodiments, the trench 135 is referred to as a cut metal gate trench, or a CMG trench.

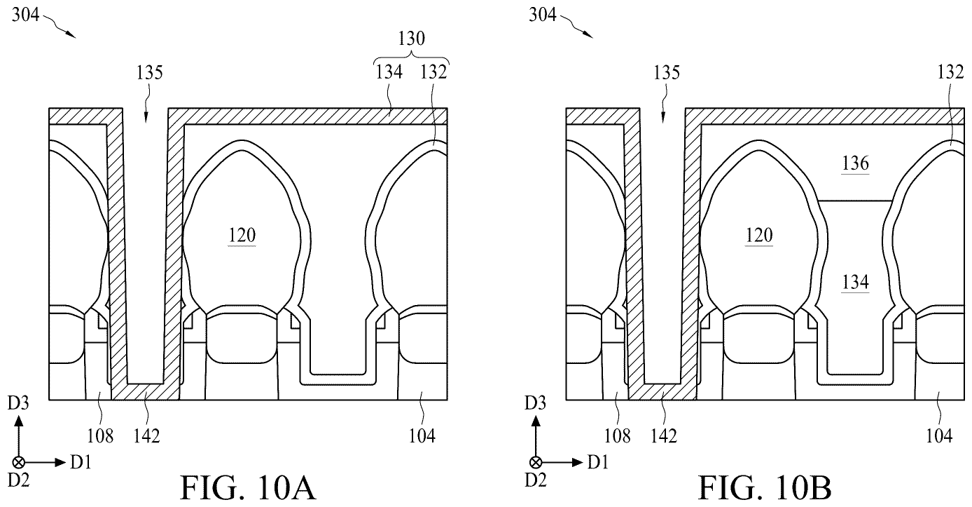

In operation 26, a multi-layered isolation structure 110 is formed in the trench 135. In some embodiments, operation 26 includes further processes. For example, in some embodiments, a first dielectric layer 142 is formed in the trench 135. Referring to FIGS. 10A and 10B, which are cross-sectional views of a portion of an intermediate semiconductor structure 304 corresponding to operation 26 in accordance with various embodiments, the first dielectric layer 142 may be conformally formed in the trench 135. In some embodiments, the first dielectric layer 142 is in contact with each layer of the metal gate structure 110. For example, the first dielectric layer 142 is in contact with the high-k gate dielectric layer 112, the work function metal layer 114, and the gap-filling metal layer 116. In some embodiments, the first dielectric layer 142 includes a dielectric material comprising silicon oxide, silicon nitride, aluminum oxide, silicon oxynitride, silicon oxycarbide, silicon carbon oxynitride, or a combination thereof. For example, the first dielectric layer 142 may be a silicon nitride layer. In some embodiments, a thickness of the first dielectric layer 142 is between approximately 0.1 nanometer and approximately 10 nanometers, but the disclosure is not limited thereto. In some embodiments, the first dielectric layer 142 is formed by a CVD, a PECVD or other suitable deposition technique, but the disclosure is not limited thereto.

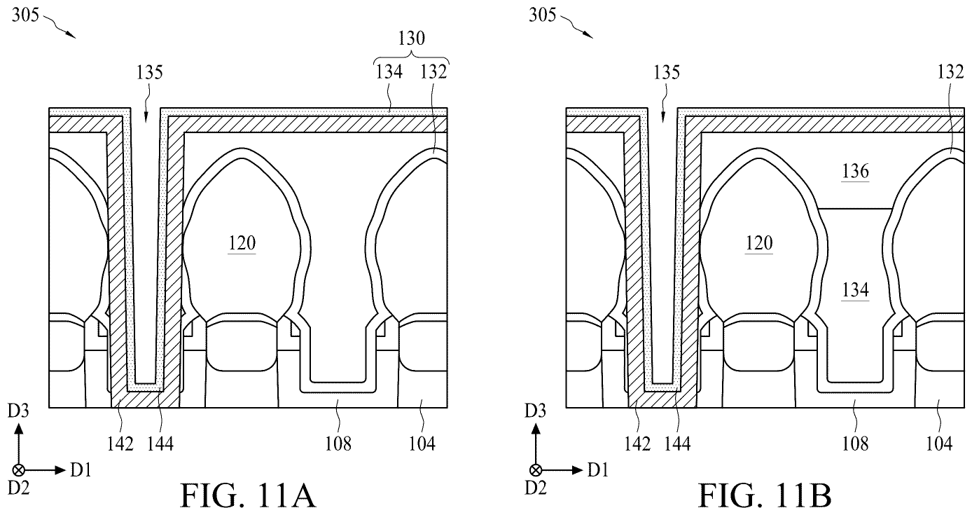

In some embodiments, operation 26 further includes forming a second dielectric layer 144 over the first dielectric layer 142. Referring to FIGS. 11A and 11B, which are cross-sectional views of a portion of an intermediate semiconductor structure 305 corresponding to operation 26 in accordance with various embodiments, the second dielectric layer 144 may be conformally formed in the trench 135. The second dielectric layer 144 also includes a dielectric material comprising silicon oxide, silicon nitride, aluminum oxide, silicon oxynitride, silicon oxycarbide, silicon carbon oxynitride, or a combination thereof. However, the dielectric material of the second dielectric layer 144 is different from the dielectric material of the first dielectric layer 142. For example, when the first dielectric layer 142 includes a silicon nitride layer, the second dielectric layer 144 may include a silicon oxide layer, but the disclosure is not limited thereto. In some embodiments, a thickness of the second dielectric layer 144 is between approximately 0.1 nanometer and approximately 10 nanometers, but the disclosure is not limited thereto. In some embodiments, the thickness of the second dielectric layer 144 is less than the thickness of the first dielectric layer 142.

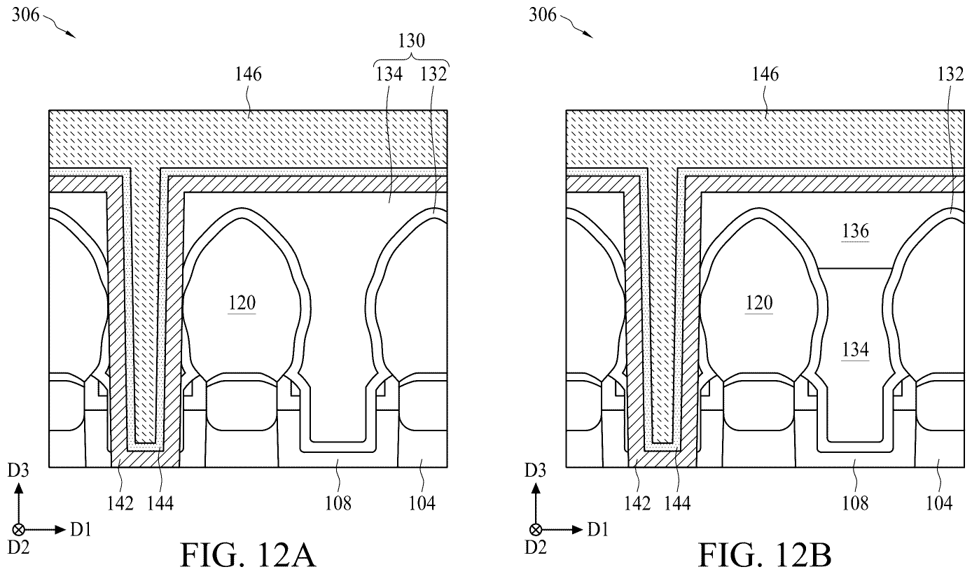

In some embodiments, operation 26 further includes forming a third dielectric layer 146 over the second dielectric layer 144. Referring to FIGS. 12A and 12B, which are cross-sectional views of intermediate semiconductor structures 306 corresponding to operation 26 in accordance with various embodiments, the trench 135 is filled with the third dielectric layer 146. The third dielectric layer 146 also includes a dielectric material including the abovementioned dielectric materials with other dopants. For examples but not limited thereto, the dopants may include silicon, aluminum, hafnium, oxygen, nitrogen, titanium, or combinations thereof. Due to the dopants in the dielectric materials, a hardness of the third dielectric layer 146 is greater than a hardness of the first dielectric layer 142, and greater than a hardness of the second dielectric layer 144. In some embodiments, a thickness of the third dielectric layer 146 is greater than the thickness of the first dielectric layer 142, and greater than the thickness of the second dielectric layer 144. In some embodiments, the thickness of the third dielectric layer 146 is between approximately 1 nanometer and approximately 20 nanometers, but the disclosure is not limited thereto.

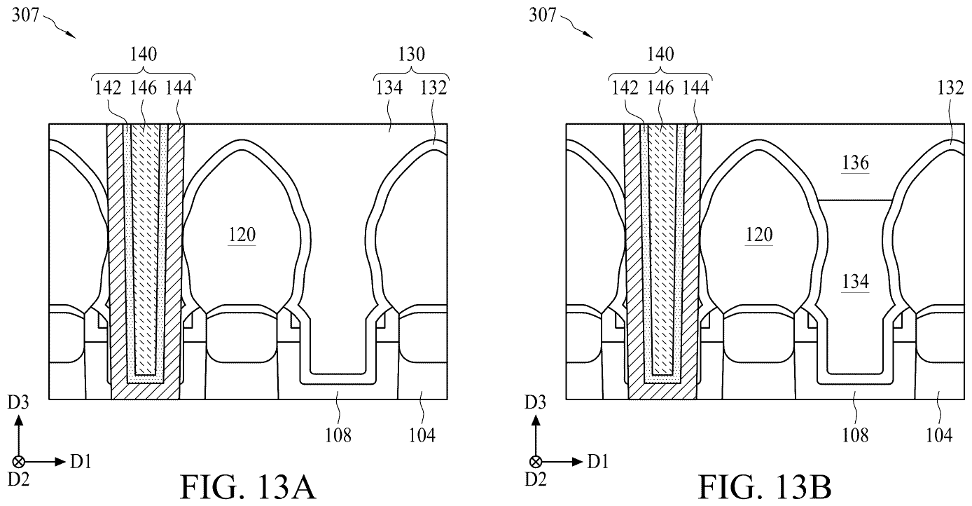

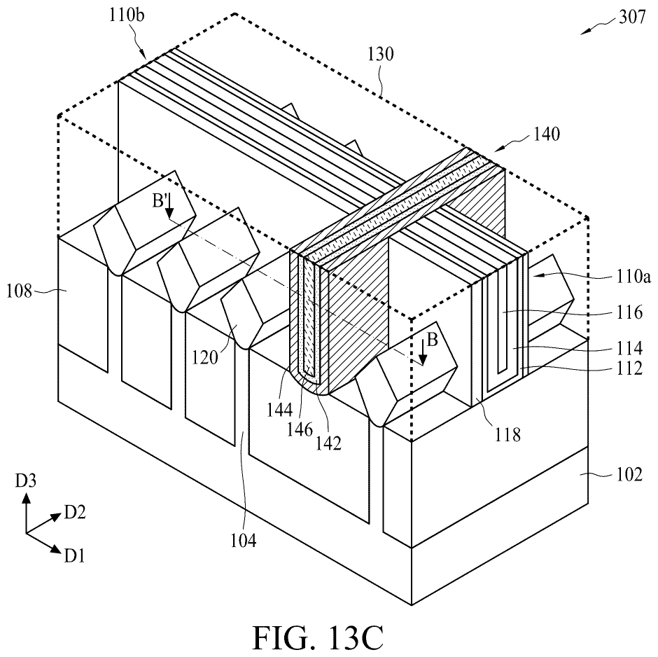

In some embodiments, operation 26 further includes removing superfluous portions of the first dielectric layer 142, the second dielectric layer 144 and the third dielectric layer 146 to obtain a substantially flat surface. Please refer to FIGS. 13A to 13C, wherein FIG. 13C is a perspective view of an intermediate semiconductor structure 307 corresponding to operation 26, and FIGS. 13A and 13B are cross-sectional views taken along the line B-B′ of FIG. 13C in accordance with various embodiments. As shown in FIGS. 13A to 13C, superfluous portions of the first dielectric layer 142, the second dielectric layer 144 and the third dielectric layer 146 are removed to form the multi-layered isolation structure 140. A top surface of the multi-layered isolation structure 140 is aligned or level with the top surface of the dielectric structure 130. In some embodiments, the third dielectric layer 146 is referred to as a hard core in the multi-layered isolation structure 140.

The multi-layered isolation structure 140 helps to electrically isolate the first metal gate structure 110a and the second metal gate structure 110b from each other. In some embodiments, the multi-layered isolation structure 140 is therefore referred to as a CMG isolation structure.

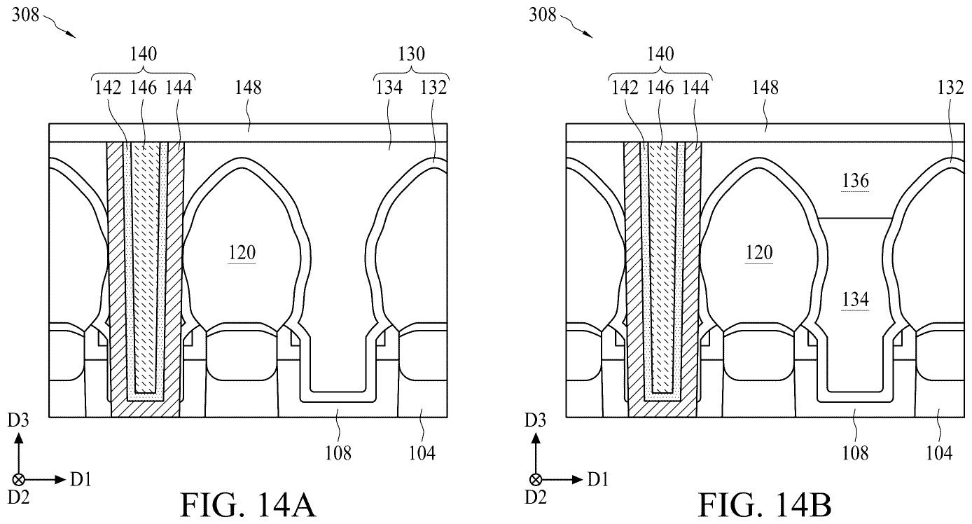

In some embodiments, an insulating layer 148 is formed over the multi-layered isolation structure 140. Referring to FIGS. 14A and 14B, which are cross-sectional views of a portion of an intermediate semiconductor structure 308 in accordance with various embodiments, the insulating layer 148 is formed over the multi-layered isolation structure 140 and the dielectric structure 130. In some embodiments, the insulating layer 148 is formed over the dielectric layer 134, as shown in FIG. 14A. In other embodiments, the insulating layer 148 is formed over the cap layer 136, as shown in FIG. 14B. In some embodiments, the insulating layer 148 includes a single layered structure. In some embodiments, the insulating layer 148 may include a silicon nitride layer, but the disclosure is not limited thereto.

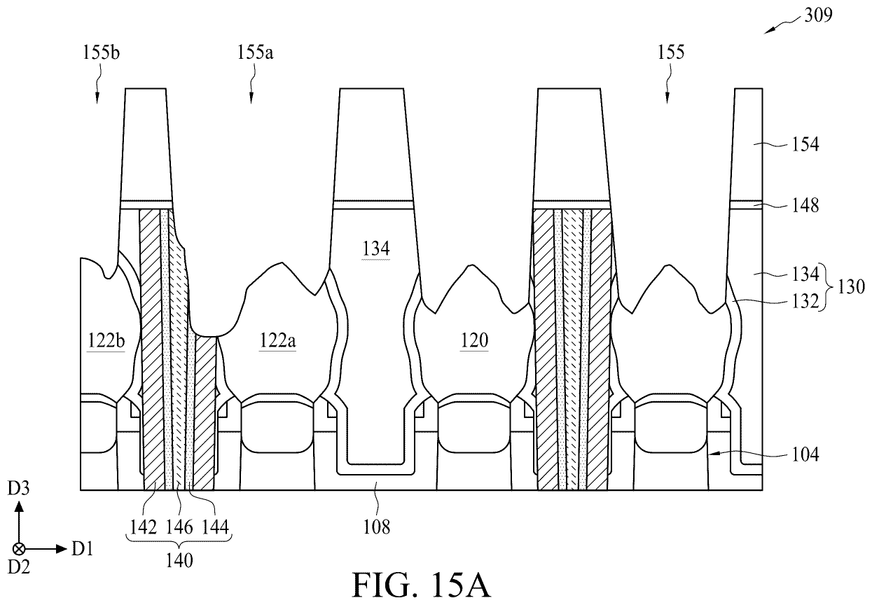

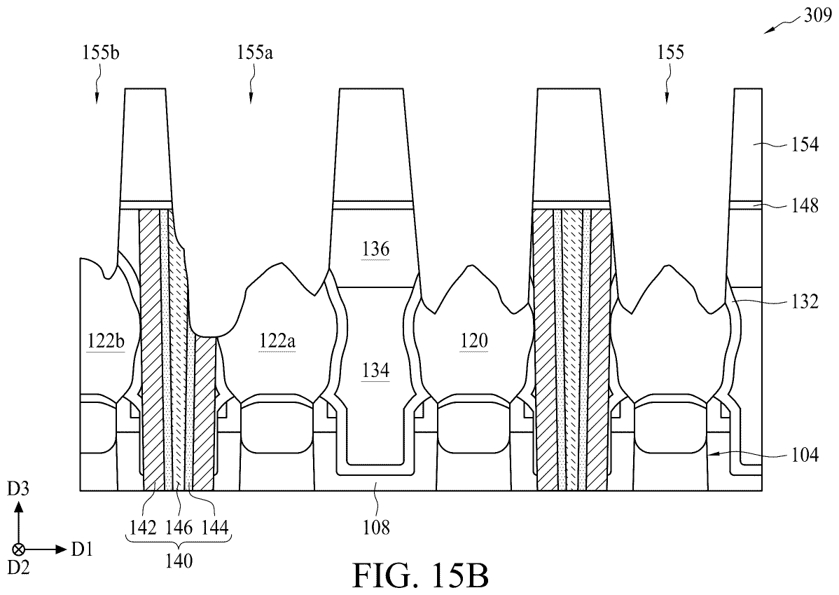

In some embodiments, in operation 27, connecting structures 150 are formed to couple to the epitaxial source/drain structures 120. In some embodiments, operation 27 includes further processes. For example, referring to FIGS. 15A and 15B, which are cross-sectional views of a portion of an intermediate semiconductor structure 309 corresponding to operation 27, a dielectric layer 154 is formed over the insulating layer 148. In some embodiments, a thickness of the dielectric layer 154 is greater than a thickness of the insulating layer 148. In some embodiments, a material of the dielectric layer 154 is different from a material of the insulating layer 148. In some embodiments, the ILD layer 134 may be referred to as a first ILD, and the dielectric layer 154 may be referred to as a second ILD.

Still referring to FIGS. 15A and 15B, in some embodiments, a plurality of recesses 155 are formed in the dielectric layer 154, the insulating layer 148, and the dielectric structure 130. In some embodiments, the recesses 155 are formed to penetrate through the second ILD layer 154, the insulating layer 148, the cap layer 136 (as shown in FIG. 15B), the first ILD 134, and the CESL 132 to expose a portion of the epitaxial source/drain structures 120. In some embodiments, these layers can be patterned using photolithography and etching processes that includes forming a mask layer (not shown) over the second ILD layer 154 and patterning the mask layer to form a patterned mask layer that can be used as a masking element for etching the abovementioned layers to form the recesses 155. The etching operation can include dry etching, wet etching, or other suitable etching processes. After the etching process, the patterned mask layer can be removed.

In some embodiments, the third dielectric layer 146, which is a hard core of the multi-layered isolation structure 140, helps to protect adjacent epitaxial source/drain structures 120. As mentioned above, the epitaxial source/drain structures 120 may include a first source/drain 122a that is a part of a first FinFET device and a second source/drain 122b that is a part of a second FinFET device. The first source/drain 122a and the second source/drain 122b may be arranged adjacent to each other in the first direction D1. In some embodiments, the recesses 155 may include a first recess 155a formed correspondingly to the first source/drain 122a, and a second recess 155 b formed correspondingly to the second source/drain 122b. During the forming of the recesses 150, the multi-layered isolation structure 140 that is disposed between the adjacent first and second source/drain 122a and 122b help to protect the first and second source/drain 122a and 112b from being exposed. In some embodiments, the third dielectric layer 146, which is harder than the first and second dielectric layers 142 and 144, is more stiff, and thus even if the first and second dielectric layers 142 and 144 are consumed or damaged during the etching, the third dielectric layer 146 can withstand the etching. In some embodiments, as shown in FIGS. 15A and 15B, the third dielectric layer 146 may help to protect the second source/drain 122a from being exposed through the recess 155b. In such embodiments, a dielectric loss due to the etching may be mitigated.

In some embodiments, operation 27 may further include forming a metal silicide structure over the portion of the epitaxial source/drain structures 120. In some implementations, the metal silicide structures can be formed over the epitaxial source/drain structures 120 by depositing a metal layer containing constituents suitable for promoting silicide formation, such as nickel, platinum, palladium, vanadium, titanium, cobalt, tantalum, ytterbium, zirconium, or other suitable metals. The substrate 102 is then heated to cause constituents of the epitaxial source/drain structures 120 to react with the metal constituents in the metal layer, resulting in the formation of the metal silicide structures. Any unreacted metal is then selectively removed by an etching process. The metal silicide structures can include titanium, cobalt, or nickel, and silicon, and can thus be referred to as a titanium silicide feature, a nickel silicide feature, or a cobalt silicide feature.

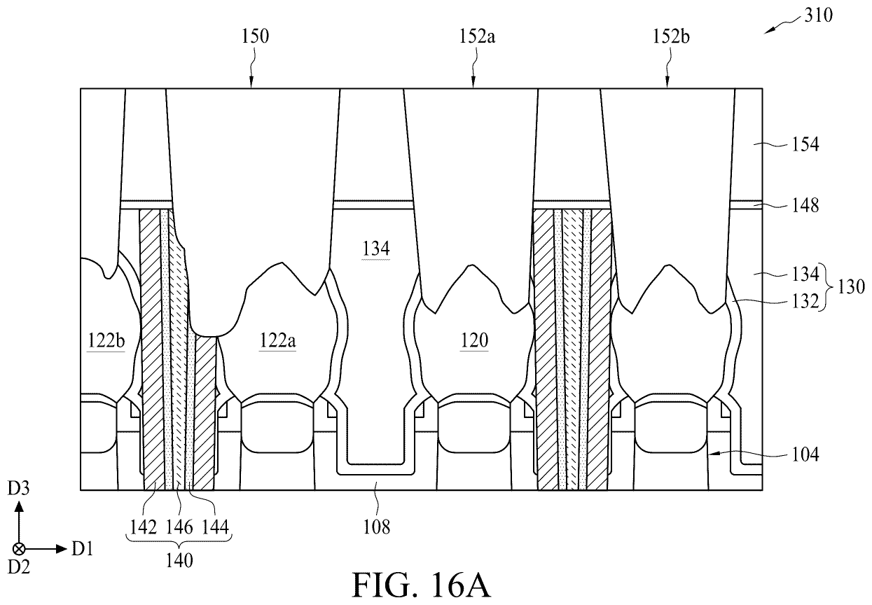

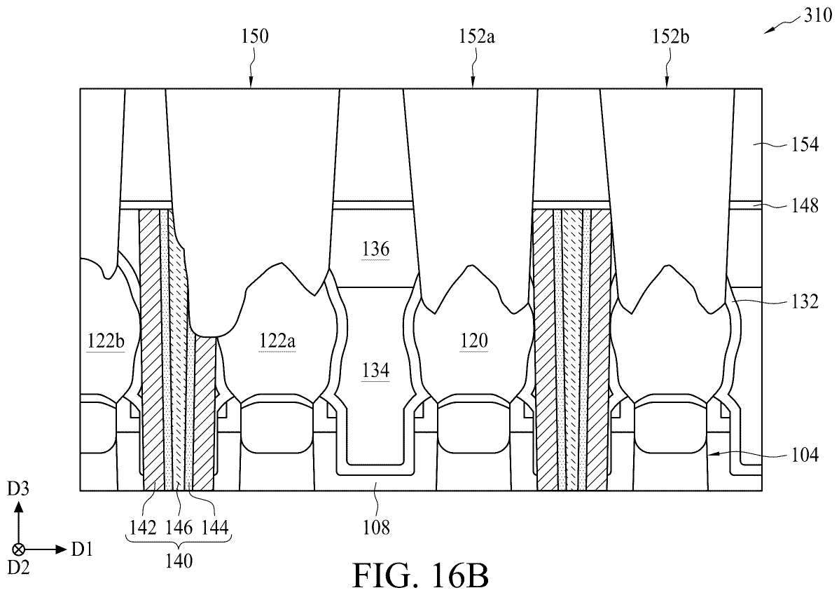

Referring to FIGS. 16A and 16B, which are cross-sectional views of a portion of an intermediate semiconductor structure 310 corresponding to operation 27, in some embodiments, connecting structures 150 are formed in the recesses 155 in operation 27. In some embodiments, the connecting structures 150 may include a first source/drain contact 152a and a second source/drain contact 152b. As shown in FIGS. 16A and 16B, the first source/drain contact 152 a is coupled to the first source/drain 122a, and the second source/drain contact 152 b is coupled to the second source/drain 122b. In some embodiments, the formation of the connecting structures 150 involves depositing conductive materials such as tungsten, cobalt, tantalum, titanium, aluminum, zirconium, gold, platinum, copper, ruthenium, or metal compounds like titanium nitride or tantalum nitride into the recesses 155. In some embodiments, deposition techniques such as CVD, PVD, ALD, or other suitable methods may be used. After the deposition, excess material may be removed through a CMP process to form the first and second source/drain contacts 152a and 152b. The first and second source/drain contacts 152a and 152b provides electrical connection between the FinFET device and a BEOL interconnection.

Accordingly, a semiconductor structure including a multi-layered isolation structure and a manufacturing method thereof are provided. The semiconductor structure includes the multi-layered isolation structure formed in a cut metal gate (CMG) operations during MEOL processes. Further, the multi-layered isolation structure formed between conductive structures, such as the abovementioned MDs serves as a barrier between two adjacent MDs. Accordingly, a process window in enlarged and yield is improved.

According to one embodiment of the present disclosure, a semiconductor structure is provided. The semiconductor structure includes a first metal gate structure, a second metal gate structure, and an isolation structure disposed between the first metal gate structure and the second metal gate structure. The first metal gate structure and the second metal gate structure extend in a first direction, and the isolation structure extends in a second direction different from the first direction. The isolation structure includes a first dielectric layer, a second dielectric layer over the first dielectric layer, and a third dielectric layer over the second dielectric layer. A material of the first dielectric layer, a material of the second dielectric layer and a material of the third dielectric layer are different from each other.

According to one embodiment of the present disclosure, a method for forming a semiconductor structure is provided. The method includes following operations. At least a gate structure extending in a first direction is formed over a substrate. A portion of the gate structure is removed to form a trench extending in a second direction different from the first direction. A first dielectric layer is conformally formed in the trench. A second dielectric layer is conformally formed over the first dielectric layer in the trench. A third dielectric layer is formed over the second dielectric layer and to fill the trench. Superfluous portions of the first dielectric layer, the second dielectric layer and the third dielectric layer are removed to form a substantially flat surface. A material of the first dielectric layer, a material of the second dielectric layer and a material of the third dielectric layer are different from each other.

According to one embodiment of the present disclosure, a method for forming a semiconductor structure is provided. The method includes following operations. At least a sacrificial gate structure extending in a first direction is formed. An epitaxial source/drain structure is formed at two sides of the sacrificial gate structure. A dielectric structure is formed to surround the sacrificial gate structure and the epitaxial source/drain structure. The sacrificial gate structure is replaced with a metal gate structure. A portion of the metal gate structure is removed to form a trench extending in a second direction different from the first direction. A multi-layered isolation structure is formed in the trench. A connecting structure coupled to the epitaxial source/drain structure is formed. The multi-layered isolation structure includes a first dielectric layer, a second dielectric layer and a third dielectric layer. A material of the first dielectric layer, a material of the second dielectric layer and a material of the third dielectric layer are different from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a first metal gate structure and a second metal gate structure extending in a first direction; and
an isolation structure disposed between the first metal gate structure and the second metal gate structure, and extending in a second direction different from the first direction, wherein the isolation structure comprises:
a first dielectric layer;
a second dielectric layer over the first dielectric layer; and
a third dielectric layer over the second dielectric layer,
wherein a material of the first dielectric layer, a material of the second dielectric layer and a material of the third dielectric layer are different from each other.

2. The semiconductor structure of claim 1, further comprising:
a first source/drain structure disposed at two sides of the first metal gate structure; and
a second source/drain structure disposed at two sides of the second metal gate structure, wherein the first source/drain structure and the second source/drain structure extend in the second direction.

3. The semiconductor structure of claim 2, wherein the isolation structure is disposed between the first source/drain structure and the second source/drain structure.

4. The semiconductor structure of claim 2, further comprising:
a first connecting structure disposed over the first source/drain structure; and
a second connecting structure disposed over the second source/drain structure,
wherein the isolation structure is disposed between the first connecting structure and the second connecting structure.

5. The semiconductor structure of claim 1, wherein a thickness of the third dielectric layer is greater than a thickness of the first dielectric layer.

6. The semiconductor structure of claim 1, wherein a thickness of the third dielectric layer is greater than a thickness of the second dielectric layer.

7. The semiconductor structure of claim 1, wherein the first dielectric layer comprises a silicon nitride layer, and the second dielectric layer comprises a silicon oxide layer.

8. The semiconductor structure of claim 1, wherein the third dielectric layer comprise a dielectric material with dopants.

9. A method for forming a semiconductor structure, comprising:
forming at least a gate structure extending in a first direction over a substrate;
removing a portion of the gate structure to form a trench extending in a second direction different from the first direction;
conformally forming a first dielectric layer in the trench;
conformally forming a second dielectric layer over the first dielectric layer in the trench;
forming a third dielectric layer over the second dielectric layer to fill the trench; and
removing superfluous potions of the first dielectric layer, the second dielectric layer and the third dielectric layer to form a substantially flat surface,
wherein a material of the first dielectric layer, a material of the second dielectric layer and a material of the third dielectric layer are different from each other.

10. The method of claim 9, wherein a thickness of the third dielectric layer is greater than a thickness of the first dielectric layer.

11. The method of claim 9, wherein a thickness of the third dielectric layer is greater than a thickness of the second dielectric layer.

12. The method of claim 9, wherein the first dielectric layer comprises a silicon nitride layer.

13. The method of claim 9, wherein the second dielectric layer comprises a silicon oxide layer.

14. A method for forming a semiconductor structure, comprising:
forming at least a sacrificial gate structure extending in a first direction;
forming an epitaxial source/drain structure at two sides of the sacrificial gate structure;
forming a dielectric structure surrounding the sacrificial gate structure and the epitaxial source/drain structure;
replacing the sacrificial gate structure with a metal gate structure;
removing a portion of the metal gate structure to form a trench extending in a second direction different from the first direction;
forming a multi-layered isolation structure in the trench; and
forming a connecting structure coupled to the epitaxial source/drain structure,
wherein the multi-layered isolation structure comprises a first dielectric layer, a second dielectric layer and a third dielectric layer, and
wherein a material of the first dielectric layer, a material of the second dielectric layer, and a material of the third dielectric layer are different from each other.

15. The method of claim 14, wherein a top surface of the multi-layered isolation structure is flush with a top surface of the dielectric structure.

16. The method of claim 14, further comprising forming an insulating layer covering the dielectric structure and the multi-layered isolation structure.

17. The method of claim 14, wherein the forming of the multi-layered isolation structure comprises:
conformally forming a first dielectric layer in the trench;
conformally forming a second dielectric layer over the first dielectric layer in the trench;
forming a third dielectric layer over the second dielectric layer to fill the trench; and
removing superfluous portions of the first dielectric layer, the second dielectric layer and the third dielectric layer to form a substantially flat surface,
wherein a material of the first dielectric layer, a material of the second dielectric layer and a material of the third dielectric layer are different from each other.

18. The method of claim 17, wherein a thickness of the third dielectric layer is greater than a thickness of the first dielectric layer, and greater than a thickness of the second dielectric layer.

19. The method of claim 17, wherein the first dielectric layer comprises a silicon nitride layer, and the second dielectric layer comprises a silicon oxide layer.

20. The method of claim 14, wherein the forming of the connecting structure comprises:
removing a portion of the dielectric structure and a portion of the multi-layered structure to form a recess exposing a portion of the epitaxial source/drain structure;
forming a metal silicide structure over the portion of the epitaxial source/drain structure; and
forming the connecting structure in the recess.
